(19) United States
(12) Patent Application Publication
(10) Pub. No.: US 2026/0136499 A1
(43) Pub. Date: May 14, 2026

(54) HEAT DISSIPATION MECHANISM

(71) Applicant: ASUSTeK COMPUTER INC., Taipei City (TW)

(72) Inventors: Sung-Chuan Huang, Taipei City (TW); Ing-Jer Chiou, Taipei City (TW)

(73) Assignee: ASUSTeK COMPUTER INC., Taipei City (TW)

(21) Appl. No.: 18/964,702

(22) Filed: Dec. 2, 2024

(30) Foreign Application Priority Data
Nov. 12, 2024 (TW) 113143348

(51) Int. Cl. H05K 7/20; G06F 1/20

(52) U.S. Cl. CPC H05K 7/20336; G06F 1/20; H05K 7/20154; H05K 7/20318

(57) ABSTRACT

Provided is a heat dissipation mechanism for a laptop computer. The laptop computer includes at least one heat source. The heat dissipation mechanism includes a vapor chamber, multiple columns, a capillary structure, a working fluid, multiple first fins, and at least one fan. The vapor chamber has a first surface and a second surface opposite to each other. A first chamber is formed between the first surface and the second surface. The second surface contacts the heat source. The columns are formed by the second surface protruding outward. Each of the columns has a second chamber, communicating with the first chamber to form a closed chamber body. The capillary structure is disposed on wall surfaces of the first chamber and the second chamber. The working fluid is filled in the first chamber and the second chamber.

### CROSS-REFERENCE TO RELATED APPLICATION

This application claims the priority benefit of Taiwan application serial no. 113143348, filed on Nov. 12, 2024. The entirety of the above-mentioned patent application is hereby incorporated by reference herein and made a part of this specification.

### BACKGROUND

### Technical Field

The disclosure is about a heat dissipation mechanism.

### Description of Related Art

The operation of electronic devices is accompanied by the generation of a large amount of heat energy. If the heat energy cannot be effectively removed, the internal electronic components may be overheated, leading to problems such as functional failures or system crash. Therefore, electronic devices are usually provided with corresponding heat dissipation systems to ensure that the components do not exceed a preset range of operating temperatures during operation.

Taking a notebook computer as an example, the notebook computer is configured with a heat dissipation mechanism including heat pipes, fans and heat dissipation fins. However, with the rapid advancement of technology, the rate of product update for notebook computers has also increased. Various models are applied for different needs every year, which means that the heat dissipation mechanism in the models also need to be adjusted in response to the models or needs, causing an increase in burden and cost for the production of the heat dissipation mechanism.

Accordingly, how to provide a modular heat dissipation mechanism to facilitate production and respond to the different models and needs is a topic that relevant technical personnel need to think about and solve.

### SUMMARY

The disclosure provides a heat dissipation mechanism for a notebook computer. The heat dissipation mechanism provides modular components to allow the heat dissipation mechanism to be adjusted in response to different models or needs.

The heat dissipation mechanism in the disclosure is adapted for a notebook computer. The notebook computer includes at least one heat source. The heat dissipation mechanism includes a vapor chamber, multiple columns, a capillary structure, a working fluid, multiple first fins, and at least one fan. The vapor chamber has a first surface and a second surface opposite to each other. A first chamber is formed between the first surface and the second surface. The second surface is adapted to contact the heat source. The columns are formed by the second surface protruding outward. Each of the columns has a second chamber, and the second chambers are respectively communicated with the first chamber and form a closed chamber body with the first chamber. The capillary structure is disposed on wall surfaces of the first chamber and the second chambers. The working fluid is filled in the first chamber and the second chambers. The first fins are located on the second surface and sleeved on the columns in layers. Each of the first fins is a least part that surrounds the column. The fan is disposed in the notebook computer. The fan has at least one outlet, and the outlet is facing the first fins.

Based on the above, in the heat dissipation mechanism of the notebook computer in the disclosure, a basic structure is formed by the vapor chamber with the first chamber in conjunction with the multiple columns with the second chambers. The second surface of the vapor chamber is configured to be in thermal contact with the heat source of the notebook computer, and the multiple first fins are respectively sleeved on the columns located on the second surface, and then the capillary structure is disposed on the inner wall surface of the vapor chamber and the inner wall surfaces of the columns and is filled with the working fluid. In this way, the capillary structure may extend from the first chamber to the second chambers, which also means that the working fluid in the first chamber may absorb heat from the heat source and convert from a liquid state to a vapor state, and then be transmitted from the first chamber to the second chambers. Since the first fins layered on the outside of the columns receive airflow from the fan and are allowed to gradually dissipate heat, the working fluid converts from the vapor state to the liquid state in the second chambers to facilitate the working fluid to flow back to the first chamber again along the capillary structure.

Based on the above, since the second chambers stand on the first chamber like chimneys, the transmission of the working fluid in the vapor state is facilitated in conjunction with the first chamber where the working fluid in the liquid state flows back to the vapor chamber along the capillary structure to allow the working fluid to form a heat dissipation cycle between the vapor chamber and the columns due to phase changes to achieve the heat dissipation effect for the heat source.

Furthermore, since the fins are sleeved on the columns, the dimension and quantity of the columns and the dimension and quantity of the first fins thereon may be increased or decreased according to heat dissipation needs. Simply put, when the heat dissipation need is increased, a greater quantity or a longer dimension of the columns and the first fins may be used to increase the heat dissipation capacity accordingly. In this way, a modular structure formed by the columns and the first fins can effectively respond to notebook computers of different models and different heat dissipation needs, and can meet the heat dissipation needs through a simple increase and decrease, improving the convenience and scope of application in design and manufacturing for the heat dissipation mechanism of the notebook computer.

### BRIEF DESCRIPTION OF THE DRAWINGS

FIG. 1 is a schematic view of some components of a notebook computer according to an embodiment of the disclosure.

FIG. 2 is an exploded view of the heat dissipation mechanism of FIG. 1.

FIG. 3 is a partial cross-sectional view of a heat dissipation mechanism.

FIG. 4 is a cross-sectional view corresponding to a specific part of FIG. 3.

FIG. 5 is a cross-sectional view of a heat dissipation mechanism from another perspective.

FIG. 6 is an exploded schematic view of columns and fins in another embodiment of the disclosure.

FIG. 7 is a top view of a heat dissipation mechanism.

FIG. 8 is a top view of a heat dissipation mechanism of another embodiment of the disclosure.

### DESCRIPTION OF THE EMBODIMENTS

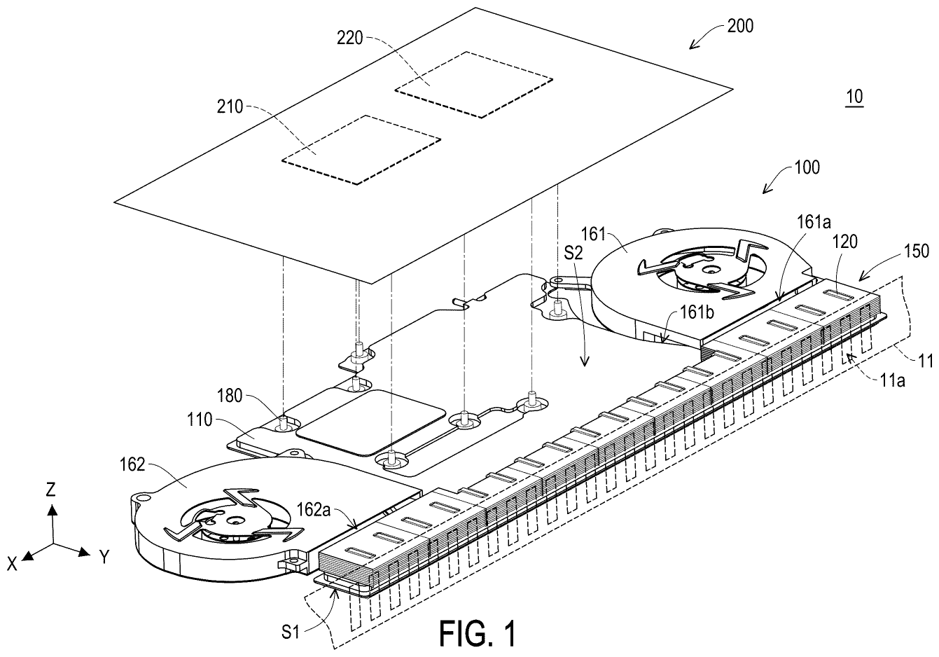

FIG. 1 is a schematic view of some components of a notebook computer according to an embodiment of the disclosure. Cartesian coordinates XYZ are provided here to facilitate component description. Please refer to FIG. 1. In the embodiment, the notebook computer 10 includes a casing 11, an electronic board 200 and a heat dissipation mechanism 100 that are disposed in the casing 11. The electronic board 200 is, for example, a motherboard, on which heat sources 210 and 220 are disposed, such as a central processing unit and a display chip. The heat dissipation mechanism 100 includes a vapor chamber 110, multiple columns 120, and multiple first fins 150, and at least one fan (two fans are taken as an example here, that is, a first fan 161 and a second fan 162). The vapor chamber 110 is a closed chamber with a first surface S1 and a second surface S2 opposite to each other, and the second surface S2 is in thermal contact with the heat sources 210 and 220. The columns 120 are vertically disposed on the second surface S2 of the vapor chamber 110 respectively, and the first fins 150 are sleeved on the columns 120. In another embodiment, both the first surface S1 and the second surface S2 are in thermal contact with the heat source, and the disclosure is not limited thereto.

As shown in FIG. 1, the columns 120 in the embodiment are arranged on one side of the vapor chamber 110 along the X-axis. If the columns 120 and the first fins 150 are used as a reference, the first fan 161 and the second fan 162 are located on the same side of the columns 120 and the first fins 150, and are opposite to heat dissipation holes 11a of the casing 11 across the columns 120 and the first fins 150. The first fan 161 and the second fan 162 respectively generate airflow, flowing out from a first outlet 161a and a second outlet 162a, blowing to the columns 120 and the first fins 150, and then discharged from the casing 11 through the heat dissipation holes 11a to dissipate heat for the columns 120 and the first fins 150.

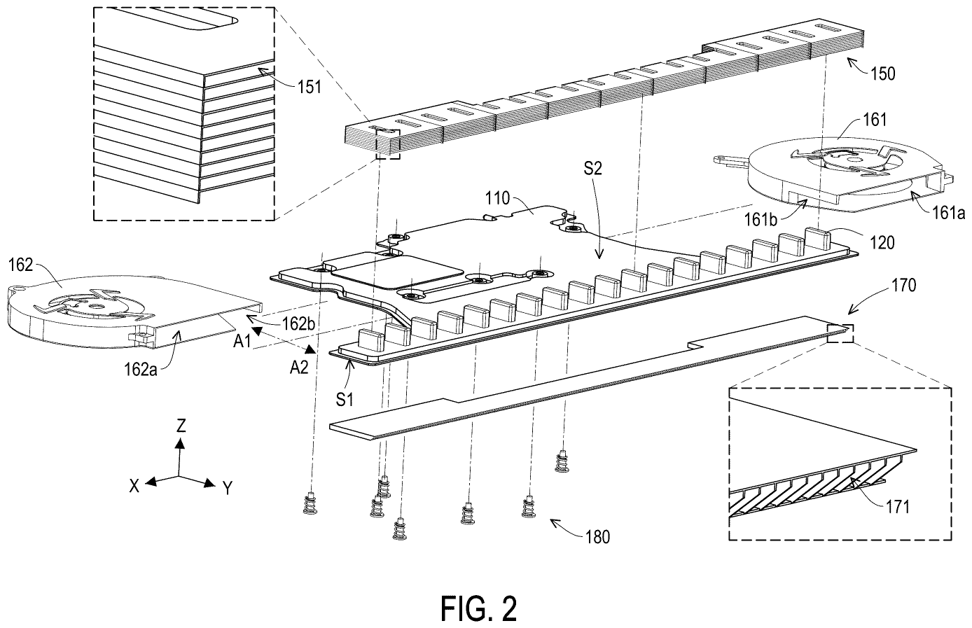

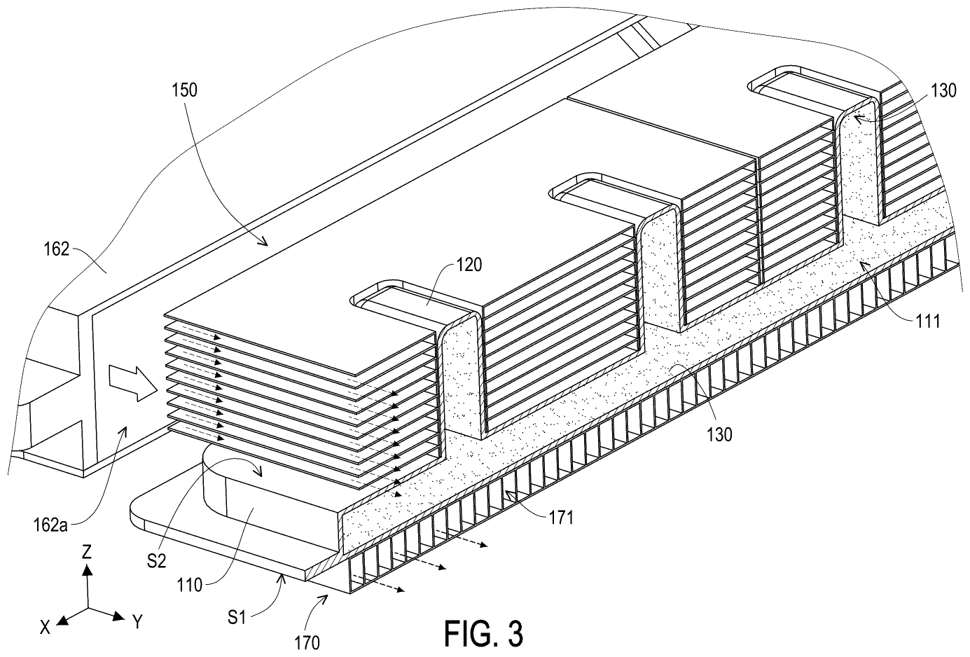

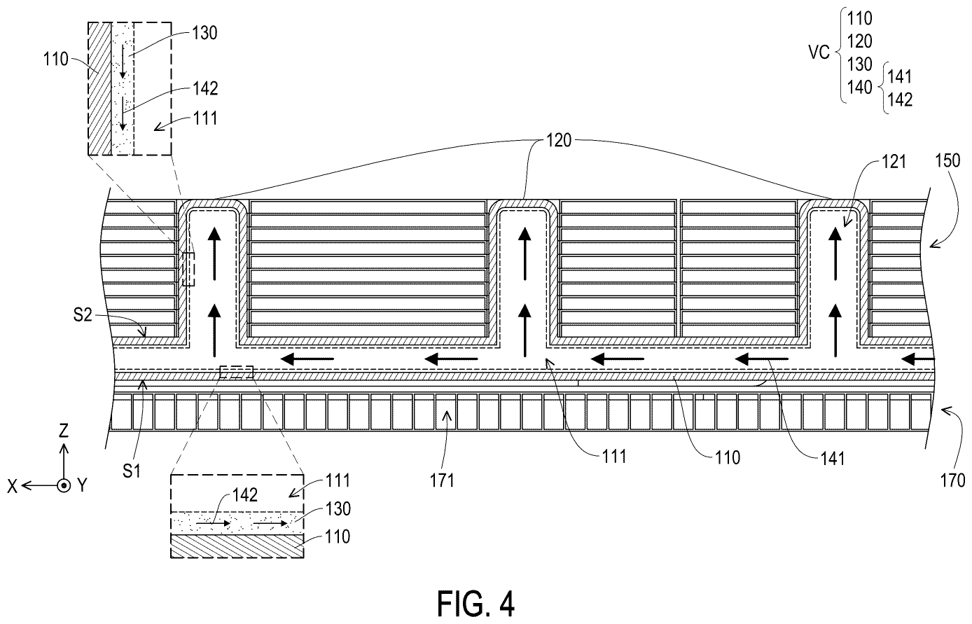

FIG. 2 is an exploded view of the heat dissipation mechanism of FIG. 1. FIG. 3 is a partial cross-sectional view of a heat dissipation mechanism. FIG. 4 is a cross-sectional view corresponding to a specific part of FIG. 3. Please refer to FIG. 2 to FIG. 4 at the same time. In the embodiment, the vapor chamber 110 is divided into an evaporation area A1 and a condensation area A2. The heat sources 210 and 220 (as shown in FIG. 1) are locked to the electronic board 200 through screws 180 passing through the vapor chamber 110 to be abutted to the evaporation area A1. The columns 120 and the first fins 150 are located in the condensation area A2. The first fan 161 and the second fan 162 are disposed next to two opposite sides of the evaporation area A1 of the vapor chamber 110 along the X-axis (to allow the heat sources 210 and 220 to be substantially located between the first fan 161 and the second fan 162). The first fan 161 and the second fan 162 are, for example, blowers or centrifugal fans, which suck in air from an axial direction (Z-axis) and then generate airflow that is blown out from the first outlet 161a and the second outlet 162a to the condensation area A2. As shown in FIG. 2 and FIG. 3, the first fins 150 are parallel to the vapor chamber 110 and the flow direction of the airflow (as a wide arrow shown in FIG. 3). Therefore, as shown in FIG. 3, the airflow blown out from the second outlet 162a may smoothly pass through channels 151 formed by the first fins 150 and be blown out from the first fins 150. Furthermore, the heat dissipation mechanism 100 further includes a second fin set 170 disposed on the first surface S1 of the vapor chamber 110. The first fins 150 and the second fin set 170 are located on two opposite surfaces of the vapor chamber 110. Here, multiple second fins of the second fin set 170 are perpendicular to the vapor chamber 110, but consistently, the second fins of the second fin set 170 are still parallel to the direction of the airflow to facilitate the airflow blown out from the second fan 162 to be blown out through channels 171 of the second fin set 170.

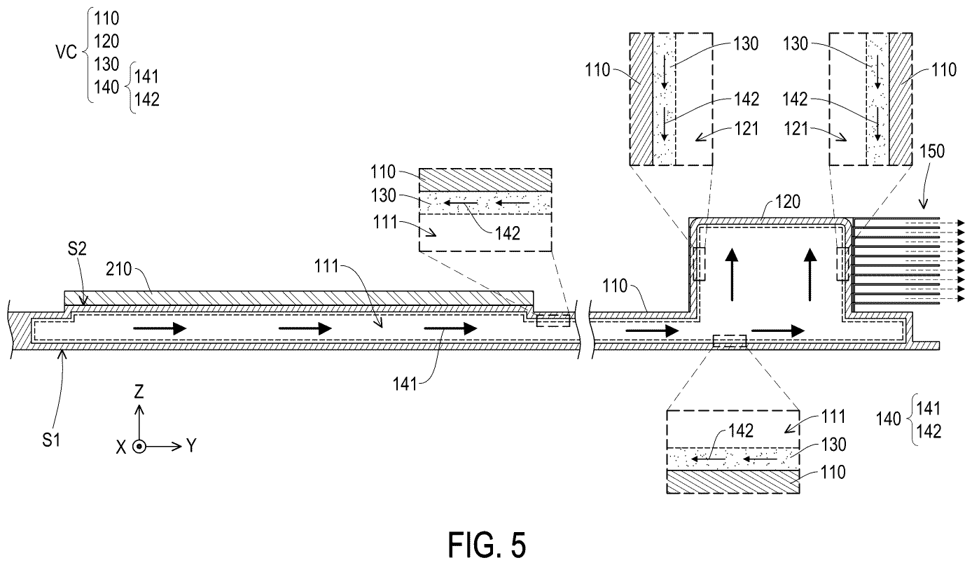

FIG. 4 is a cross-sectional view corresponding to a specific part of FIG. 3, which is equivalent to a front view of the components in FIG. 3 from the Y-axis. FIG. 5 is a cross-sectional view of a heat dissipation mechanism from another perspective, which is equivalent to a front view of the heat dissipation mechanism 100 in FIG. 1 from the X-axis. Please refer to FIG. 2, FIG. 4 and FIG. 5 at the same time. In the embodiment, the vapor chamber 110 has a first chamber 111 formed between the first surface S1 and the second surface S2. Each of the columns 120 has a second chamber 121, and the second chambers 121 are individually communicated with the first chamber 111. The heat dissipation mechanism 100 further includes a capillary structure 130 and a working fluid 140. The capillary structure 130 is continuously disposed along the inner wall surface of the vapor chamber 110 and the inner wall surface of the columns 120, and the working fluid 140 is filled in the first chamber 111 and the second chambers 121. Accordingly, after the working fluid 142 in a liquid state absorbs heat from the heat sources 210 and 220 in the evaporation area A1 of the vapor chamber 110, a phase change is generated to convert the working fluid 141 into a vapor state, which is transmitted to the condensation area A2 provided with the columns 120 and the first fins 150. Since there is airflow from the first fan 161 and the second fan 162 to dissipate heat for the first fins 150, the working fluid 141 flowing to the condensation area A2 may gradually cool down and phase change the working fluid 142 into the liquid state in the second chamber 121, and transmit back to the evaporation area A1 through the capillary structure 130 to form a complete phase change cycle. Here, the vapor chamber 110, the columns 120, the capillary structure 130 and the working fluid 140 (141 and 142) compose an integrated vapor chamber structure VC, that is, the first chamber 111 and the second chamber 121 form a closed chamber body to complete the heat dissipation effect for the heat sources 210 and 220 through phase changes of the working fluid 140.

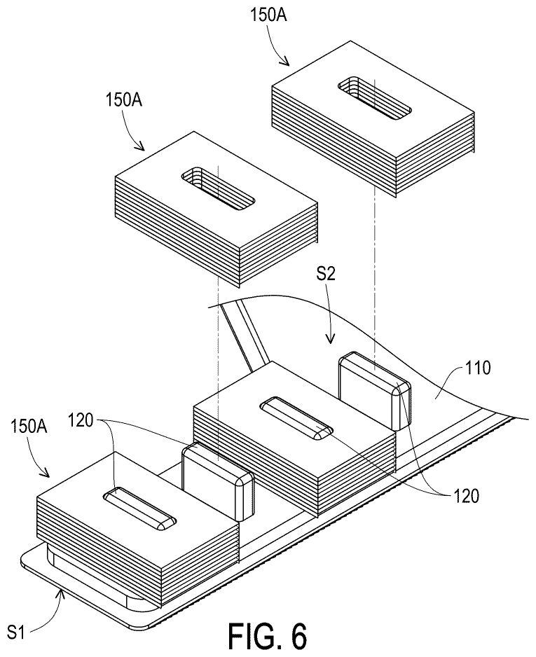

FIG. 6 is an exploded schematic view of columns and fins in another embodiment of the disclosure. Please refer to FIG. 6 and compare with FIG. 2 or FIG. 3. In the embodiment, each of the first fins 150 and the first fins 150A is substantially a least part that surrounds the column 120. The first fins 150 and the first fins 150A are divided into multiple first fin sets, and each of the first fin sets is sleeved on at least one of the columns 120. As shown in FIG. 2 or FIG. 3, the first fin set divided by the first fins 150 is sleeved on two of the columns 120, while the first fin set formed by the first fins 150A shown in FIG. 6 is only disposed on one of the columns 120. There is no limit to the quantity of the columns 120 that the first fins 150 or the first fins 150A need to be sleeved on. The first fins 150 and the first fins 150A may be modularized according to needs, but there is no limit to the quantity of each modularized first fins 150 and first fins 150A, and the columns 120 to be sleeved on. For example, when the heat dissipation efficiency needs to be increased, each of the columns 120 may be covered with a set of the first fins 150A as shown in FIG. 6. Looking back at FIG. 2 or FIG. 3, if the assembly process of the first fins 150 and the columns 120 is to be simplified, or the heat dissipation performance does not need to be too high, the first fin set formed by the first fins 150 may be sleeved on the multiple (more than two) columns 120. Here, the bonding of the first fins 150, the first fins 150A and the columns 120, and the bonding of the columns 120 and the vapor chamber 110 may be achieved through welding.

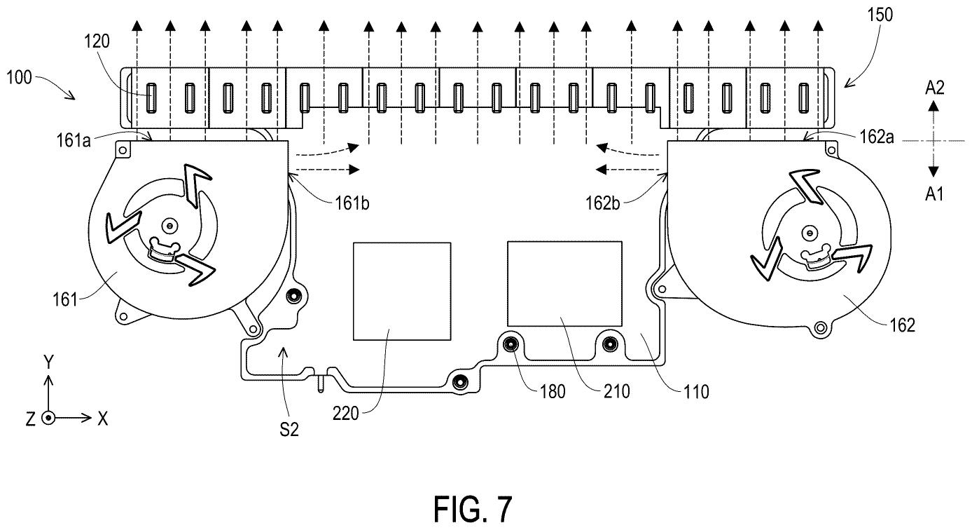

FIG. 7 is a top view of a heat dissipation mechanism. Please refer to FIG. 7 and compare with FIG. 1 or FIG. 2. In the embodiment, in addition to the first outlet 161a and the second outlet 162a of the first fan 161 and the second fan 162 directly facing parts of the first fins 150 and the column 120s to achieve the heat dissipation effect, the columns 120 and the first fins 150 are arranged along the X-axis to correspond to the heat dissipating holes 11a of the casing 11 (as shown in FIG. 1) in response to the configuration of other system components in the notebook computer 10 and the heat that may accumulate therein. Therefore, according to the embodiment, there are still the columns 120 and the first fins 150 that are not directly facing the first fan 161 and the second fan 162. Furthermore, the first fan 161 and the second fan 162 further have a first auxiliary outlet 161b and a second auxiliary outlet 162b opposite to each other across the heat sources 210 and 220 and both facing the evaporation area A1 of the vapor chamber 110. In this way, part of the airflow of the first fan 161 and the second fan 162 may be respectively blown from the first auxiliary outlet 161b and the second auxiliary outlet 162b to the evaporation area A1 and the heat sources 210 and 220 thereon to be accumulated in the casing 11, and then blown toward a Y-axial direction where the columns 120 and the first fins 150 are not directly faced by the first fan 161 and the second fan 162, and then discharged out of the casing 11 through the heat dissipation holes 11a. At the same time, the airflow may further provide heat dissipation to the columns 120 and the first fins 150 that are not directly faced by the first fan 161 and the second fan 162. As shown in FIG. 1 and FIG. 7, the first fins 150 located in the middle section that are not directly facing the first fan 161 and the second fan 162 have shorter dimensions along the Y-axis and do not completely surround the columns 120, which may further help conduct heat through contacting the first fins 150 that are longer. In this way, an additional path of heat dissipation can be provided to the inside of the notebook computer 10.

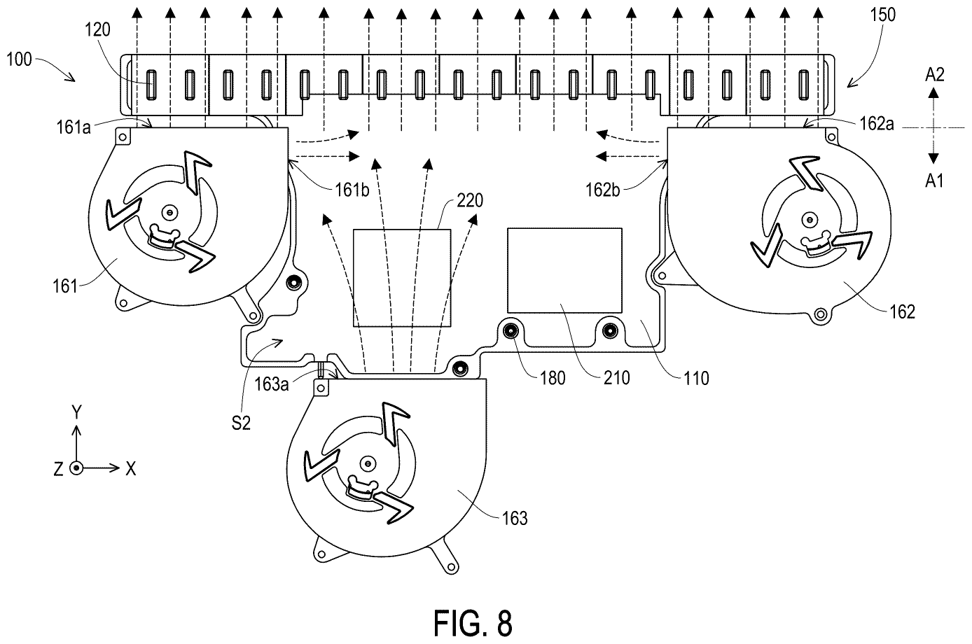

FIG. 8 is a top view of a heat dissipation mechanism of another embodiment of the disclosure. Please refer to FIG. 8. Different from the foregoing embodiment, the heat dissipation mechanism of the embodiment includes the first fan 161, the second fan 162 and a third fan 163, which are respectively disposed in three different side edges of the evaporation areas A1 adjacent to the vapor chamber 110. The first fan 161 and the second fan 162 have the same structural features and configurations as the foregoing embodiments, and will not be described again here. The third fan 163 of the embodiment only has a third outlet 163a (without an auxiliary outlet), facing the evaporation area A1 and the condensation area A2, and opposite to the condensation area A2 across the evaporation area A1. Here, the third fan 163 may provide an auxiliary effect to the airflow of the first fan 161 and the second fan 162, that is, the airflow blown from the first auxiliary outlet 161b and the second auxiliary outlet 162b to the evaporation area A1 and the heat sources 210 and 220 may be actively driven to the columns 120 and the first fins 150 located in the middle section, and may also increase the heat dissipation efficiency for the evaporation area A1 and the heat sources 210 and 220 thereon.

In summary, in the foregoing embodiments of the disclosure, the columns with the second chambers are vertically disposed on the vapor chamber with the first chamber. The first chamber and the second chambers are communicated with each other and are continuously formed with the capillary structure on the inner wall of the vapor chamber and the inner wall of the columns, and then the working fluid that may generate phase changes in response to temperature is filled in the first chamber and the second chambers. In this way, when the heat source is abutted with the vapor chamber, the working fluid therein may absorb heat from the heat source to phase change the working fluid into the vapor state. Then, when the working fluid travels to the condensation area, since there is airflow facing the columns and the first fins, the working fluid in the condensation area may dissipate heat and phase change the working fluid into the liquid state, and return to the condensation area again along the capillary structure to form a phase change cycle of the working fluid.

Since the second chambers stand on the first chamber like chimneys, the transmission of the working fluid that is in the vapor state due to heat absorption is facilitated in conjunction with the first chamber where the working fluid in the liquid state flows back to the vapor chamber along the capillary structure to allow the working fluid to form a heat dissipation cycle between the vapor chamber and the columns due to phase changes to achieve the heat dissipation effect for the heat source.

Furthermore, since the fins are sleeved on the columns, the dimension and quantity of the columns and the dimension and quantity of the first fins thereon may be increased or decreased according to heat dissipation needs without re-developing and manufacturing molds. Simply put, when the heat dissipation need is increased, a greater quantity or a longer dimension of the columns and the first fins may be used to increase the heat dissipation capacity accordingly. In this way, a modular structure formed by the columns and the first fins can effectively respond to notebook computers of different models and different heat dissipation needs, and can meet the heat dissipation needs through a simple increase and decrease, improving the convenience and scope of application in design and manufacturing for the heat dissipation mechanism of the notebook computer.

What is claimed is:

1. A heat dissipation mechanism for a notebook computer, the notebook computer comprising at least one heat source, the heat dissipation mechanism comprising:
a vapor chamber, having a first surface and a second surface opposite to each other, wherein a first chamber is formed between the first surface and the second surface, and the second surface is adapted to contact the at least one heat source;
a plurality of columns, formed by the second surface protruding outward, wherein each of the columns has a second chamber, and the second chambers are respectively communicated with the first chamber and form a closed chamber body with the first chamber;
a capillary structure, disposed on wall surfaces of the first chamber and the second chambers;
a working fluid, filled in the first chamber and the second chambers;
a plurality of first fins, located on the second surface, and sleeved on the columns in layers, wherein each of the first fins is a least part that surrounds the column; and
at least one fan, disposed in the notebook computer, wherein the fan has at least one outlet, and the outlet is facing the first fins.

2. The heat dissipation mechanism according to claim 1, wherein the first fins are parallel to the vapor chamber.

3. The heat dissipation mechanism according to claim 1, wherein the columns are arranged in a condensation area of the vapor chamber along an axial direction, the at least one heat source is abutted with an evaporation area of the vapor chamber, the at least one fan is located next to the evaporation area of the vapor chamber, and the outlet of the fan is facing the condensation area.

4. The heat dissipation mechanism according to claim 3, wherein a quantity of the at least one fan is two, located next to the evaporation area of the vapor chamber, and the at least one heat source is located between the two fans.

5. The heat dissipation mechanism according to claim 4, wherein the two fans each have an auxiliary outlet, opposite to each other and facing the evaporation area of the vapor chamber.

6. The heat dissipation mechanism according to claim 1, wherein the first fins are divided into multiple first fin sets, and each of the first fin sets is sleeved on at least one of the columns.

7. The heat dissipation mechanism according to claim 1, further comprising a second fin set, disposed on the first surface of the vapor chamber, wherein the first fins and the second fin set are located on two opposite surfaces of the vapor chamber.

8. The heat dissipation mechanism according to claim 7, wherein a plurality of second fins of the second fin set are respectively perpendicular to the vapor chamber.

9. The heat dissipation mechanism according to claim 1, wherein the at least one fan comprises a first fan, a second fan and a third fan that are respectively adjacent to three different side edges of an evaporation area of the vapor chamber, the first fan has a first outlet and a first auxiliary outlet, the second fan has a second outlet and a second auxiliary outlet, the third fan has a third outlet, wherein the first outlet and the second outlet each are facing a condensation area of the vapor chamber, the first auxiliary outlet and the second auxiliary outlet are opposite to each other across the vapor chamber and the heat source thereon, and the third outlet is facing the evaporation area and the condensation area, and is opposite to the condensation area across the evaporation area.
